(19) United States
(12) Patent Application Publication
(10) Pub. No.: US 2026/0371285 A1
(43) Pub. Date: Nov. 19, 2026

(54) INFORMATION PROCESSING METHODS AND APPARATUSES, COMMUNICATION DEVICE AND STORAGE MEDIUM

(71) Applicant: Beijing Xiaomi Mobile Software Co., Ltd., Beijing (CN)

(72) Inventors: Xiaolong LI, Beijing (CN); Qin MU, Beijing (CN)

(73) Assignee: Beijing Xiaomi Mobile Software Co., Ltd., Beijing (CN)

(21) Appl. No.: 19/126,482

(22) PCT Filed: Nov. 4, 2022
(86) PCT No.: PCT/CN2022/130139

§ 371 Date: May 1, 2025

(51) Int. Cl. H04W 64/00; H04W 8/20

(52) U.S. Cl. CPC H04W 64/00; H04W 8/20

(57) ABSTRACT

Provided in the embodiments of the present disclosure are information processing methods and apparatuses, a communication device and a storage medium. A method is executed by a first communication device, and comprises: receiving a data set from a second communication device; and, by using the data set, training an artificial intelligence (AI)/machine learning (ML) model, the AI/ML model being at least used for positioning.

### CROSS-REFERENCE TO RELATED APPLICATION

The application is a U.S. National Stage of International Application No. PCT/CN2022/130139 filed on Nov. 4, 2022, the entire content of which is incorporated herein by reference.

### TECHNICAL FIELD

The present disclosure relates to the technical field of wireless communication but is not limited to the technical field of wireless communication, and in particular, to an information processing method and apparatus, a communication device and a storage medium.

### BACKGROUND

With the development of artificial intelligence (AI) and machine learning (ML), AI/ML is applied to the 5th generation new radio (5G NR). For example, AI/ML can be used for positioning of devices.

For example, AI/ML models can be used for positioning of devices such as user equipment (UE).

### SUMMARY

Embodiments of the present disclosure provide an information processing method and apparatus, a communication device, and a storage medium.

A first aspect of the embodiments of the present disclosure provides an information processing method, which is performed by a first communication device, and the method includes: receiving a data set from a second communication device; and training an AI/ML model using the data set, where the AI/ML model is at least used for positioning.

A second aspect of the embodiments of the present disclosure provides an information processing method, where the method is performed by a second communication device, and the method includes: sending a data set to a first communication device; where the data set is used to train an artificial intelligence (AL)/machine learning (ML) model, where the AI/ML model is at least used for positioning.

A third aspect of the embodiments of the present disclosure provides an information processing apparatus, where the apparatus includes: a receiving module, configured to receive a data set from a second communication device; and a training module, configured to train an artificial intelligence (AI)/machine learning (ML) model using the data set, where the AI/ML model is at least used for positioning.

A fourth aspect of the embodiments of the present disclosure provides an information processing apparatus, where the apparatus includes: a sending module, configured to send a data set to a first communication device; where the data set is used to train an artificial intelligence (AL)/machine learning (ML) model, where the AI/ML model is at least used for positioning.

A fifth aspect of the embodiments of the present disclosure provides an information processing system, which includes: a first communication device and a second communication device.

The first communication device is configured to receive a data set from a second communication device and train an artificial intelligence (AI)/machine learning (ML) model using the data set, where the AI/ML model is at least used for positioning. The second communication device is configured to send a data set to the first communication device, where the data set is used for training an artificial intelligence (AL)/machine learning (ML) model, where the AI/ML model is at least used for positioning.

A sixth aspect of the embodiments of the present disclosure provides a communication device, comprising a processor, a transceiver, a memory, and an executable program stored in the memory and capable of being run by the processor, where the processor executes the information processing method provided in the first aspect or the second aspect when running the executable program.

A seventh aspect of the embodiments of the present disclosure provides a computer storage medium, which stores an executable program; after the executable program is executed by a processor, it can implement the information processing method provided in the first aspect or the second aspect.

An eighth aspect of the embodiments of the present disclosure provides a communication system, where the communication system includes: a first communication device, configured to execute the information processing method provided by any technical solution of the first aspect mentioned above; and a second communication device, configured to execute the information processing method provided by any technical solution of the first aspect mentioned above.

It should be understood that the foregoing general description and the following detailed description are exemplary and explanatory only, and do not limit the embodiments of the present disclosure.

### BRIEF DESCRIPTION OF THE DRAWINGS

The accompanying drawings, which are incorporated in and constitute a part of this specification, illustrate embodiments consistent with the present disclosure and together with the description, serve to explain principles of the embodiments of the present disclosure.

FIG. 1 is a schematic structural diagram of a wireless communication system according to an exemplary embodiment.

FIG. 2A is a schematic flowchart of an information processing method according to an exemplary embodiment.

FIG. 2B is a schematic flowchart of an information processing method according to an exemplary embodiment.

FIG. 2C is a schematic flowchart of an information processing method according to an exemplary embodiment.

FIG. 3A is a schematic flowchart of an information processing method according to an exemplary embodiment.

FIG. 3B is a schematic flowchart of an information processing method according to an exemplary embodiment.

FIG. 4A is a schematic flowchart of an information processing method according to an exemplary embodiment.

FIG. 4B is a schematic flowchart of an information processing method according to an exemplary embodiment.

FIG. 4C is a schematic flowchart of an information processing method according to an exemplary embodiment.

FIG. 4D is a schematic flowchart of an information processing method according to an exemplary embodiment.

FIG. 4E is a schematic flowchart of an information processing method according to an exemplary embodiment.

FIG. 4F is a schematic flowchart of an information processing method according to an exemplary embodiment.

FIG. 5 is a schematic structural diagram of an information processing apparatus according to an exemplary embodiment.

FIG. 6 is a schematic structural diagram of an information processing apparatus according to an exemplary embodiment.

FIG. 7 is a schematic structural diagram of a UE according to an exemplary embodiment.

FIG. 8 is a schematic structural diagram of a communication device according to an exemplary embodiment.

### DETAILED DESCRIPTION

Exemplary embodiments will be described in detail herein, examples of which are illustrated in the accompanying drawings. When the following description refers to the drawings, the same numbers in different drawings refer to the same or similar elements unless otherwise indicated. The implementations described in the following exemplary embodiments do not represent all implementations consistent with the embodiments of the present disclosure. Rather, they are merely examples of apparatus and method consistent with some aspects of the embodiments of the present disclosure.

The terms used in the embodiments of the present disclosure are for the purpose of describing specific embodiments only and are not intended to limit the embodiments of the present disclosure. As used in the present disclosure, the singular forms “a/an”, “said”, and “the” are intended to include the plural forms as well, unless the context clearly dictates otherwise. It should also be understood that the term “and/or” as used herein refers to and includes any and all possible combinations of one or more of the associated listed items.

It should be understood that although the terms first, second, third, etc. may be used to describe various information in the embodiments of the present disclosure, the information should not be limited to these terms. These terms are only used to distinguish information of the same type from each other. For example, without departing from the scope of the embodiments of the present disclosure, the first information may also be called second information, and similarly, the second information may also be called first information. Depending on the context, the word “if” as used herein may be interpreted as “when” or “upon” or “in response to determining.”

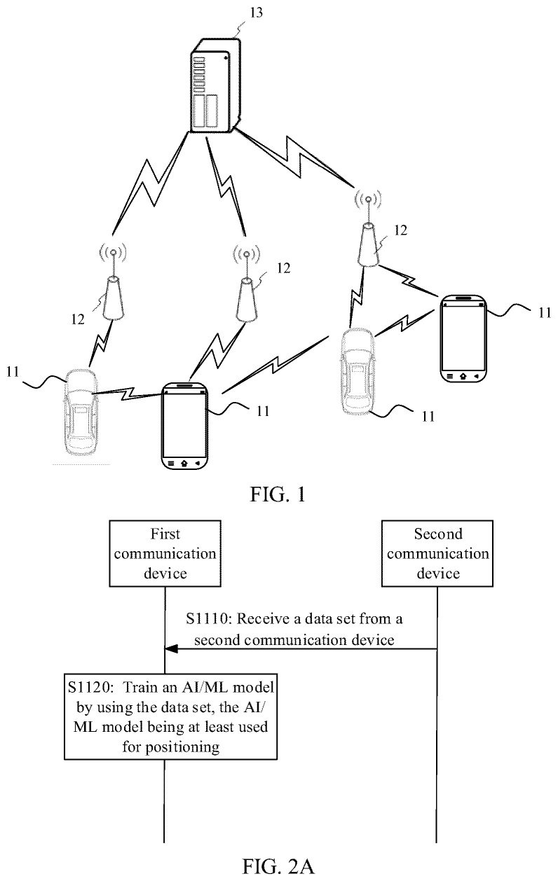

Referring to FIG. 1, which shows a schematic structural diagram of a wireless communication system provided by an embodiment of the present disclosure. As shown in the figure, the wireless communication system is a communication system based on cellular mobile communication technology, and the wireless communication system may include: several UEs 11 and several access devices 12. The wireless communication system may further include: a core network device 13.

UE 11 may be a device that provides voice and/or data connectivity to users. UE 11 can communicate with one or more core networks via a radio access network (RAN). UE 11 can be an Internet of Things UE, such as a sensor device, a mobile phone (or a cellular phone), and a computer with an Internet of Things UE. For example, it can be a fixed, portable, pocket-sized, handheld, computer-built-in, or vehicle-mounted apparatus, such as a station (STA), a subscriber unit, a subscriber station, a mobile station, a mobile, a remote station, an access point, a remote UE (remote terminal), an access UE (access terminal), a user apparatus (user terminal), a user agent, a user device, or a user UE (user equipment, UE). Alternatively, UE 11 can also be a device of an unmanned aerial vehicle. Alternatively, UE 11 can also be a vehicle-mounted device, for example, it can be an onboard computer with wireless communication function, or a wireless communication device connected to an external onboard computer. Alternatively, UE 11 may also be a roadside device, for example, a streetlight, traffic light or other roadside device with wireless communication function.

The access device 12 may be a network-side device in the wireless communication system. The wireless communication system may be the 4th generation mobile communication technology (4G) system, also known as a long-term evolution (LTE) system; or, the wireless communication system may be a 5G system, also known as a new radio (NR) system or a 5G NR system. Alternatively, the wireless communication system may be a next generation system of the 5G system. The access network in the 5G system may be called New Generation-Radio Access Network (NG-RAN). Alternatively, it may an MTC system.

The access device 12 may be an evolved access device (eNB) adopted in the 4G system. Alternatively, the access device 12 may also be an access device (gNB) adopting a centralized distributed architecture in the 5G system. When the access device 12 adopts the centralized distributed architecture, it usually includes a central unit (CU) and at least two distributed units (DU). The central unit is provided with protocol stacks of a packet data convergence protocol (PDCP) layer, a radio link layer control protocol (RLC) layer, and a media access control (MAC) layer; the distributed unit is provided with a physical (PHY) layer protocol stack. The specific implementation manner of the access device 12 is not limited in the embodiments of the present disclosure.

A wireless connection can be established between the access device 12 and the UE 11 through a wireless air interface. In different implementations, the wireless air interface is a wireless air interface based on the fourth generation mobile communication network technology (4G) standard; or, the wireless air interface is a wireless air interface based on the fifth generation mobile communication network technology (5G) standard, for example, the wireless air interface is a new air interface; or, the wireless air interface may also be a wireless air interface based on the next generation mobile communication network technology standard of 5G.

There is still a lack of relevant technical support in the related art for the training of positioning-based AI/ML models.

For AI/ML-based positioning, there may be multiple AI models for positioning, and different AI models are applied to different positioning application scenes. That is, for different positioning application scenes, different data sets are used to train AI models, thereby obtaining different AI/ML models for different positioning application scenes.

The AI/ML model for positioning can be deployed in UE, next-generation base station (gNB) and location management function (LMF). However, the entities for training AI/ML models may include UE, gNB, LMF, operation administration and maintenance (OAM) and network data analysis function (NWDAF). Therefore, UE, gNB, LMF, OAM and NWDAF need data sets to train AI/ML models. In view of this, the following provides relevant technologies for data set acquisition in the process of AI/ML model training.

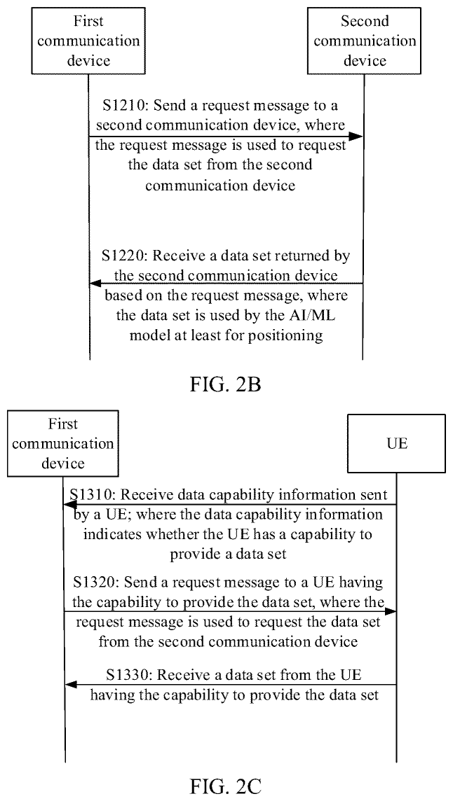

As shown in FIG. 2A, an embodiment of the present disclosure provides an information processing method, which is performed by a first communication device and includes the following steps.

In S1110: a data set is received from a second communication device.

In S1120: an artificial intelligence (AI)/machine learning (ML) model is trained using the data set, where the AI/ML model is at least used for positioning.

In some embodiments of the present disclosure, the first communication device may be any device that performs AI/ML model training. The first communication device may be a network device or a UE.

In some embodiments of the present disclosure, the network device includes but is not limited to an access network device or a core network device and/or network management device, etc.

In some embodiments of the present disclosure, the UE may be a UE with relatively strong processing capability, for example, a UE with a graphics processing unit (GPU).

The above are only examples of the first communication device, and the specific implementation is not limited to the examples.

The second communication device may be any device different from the first communication device.

The second communication device may have the capability of collecting data to form the data set, or may have the capability of forwarding the data set to the first communication device.

The data set may include any data used to train the AI/ML model. Exemplarily, the data set may include: sample data for training the AI/ML model.

The AI model may include, but is not limited to, various deep learning models. The deep learning model may include a neural network model, such as a convolutional neural network, a recurrent neural network, and/or a long short-term memory network.

The ML model may include, but is not limited to, a model generated by machine learning or device self-learning, for example, a reinforcement learning model.

After training of the AI/ML model is completed, it can be used to locate the measured object. In this way, if the training set is sample data for training the AI/ML model, the data set may include data generated during the wireless positioning process. Exemplarily, after the AI/ML model is input with the measurement result, the AI/ML model may output location information that meets the accuracy requirement and/or output location information within the maximum allowed delay.

In some embodiments of the present disclosure, the AI/ML model may be used for positioning based on the wireless capability of the access network device such as the base station. Exemplarily, the base station may include a terrestrial network (TN) base station and a non-terrestrial network (TN) base station.

In some embodiments of the present disclosure, the S1110 may include: receiving the data set actively reported by the second communication device; or sending an indication or request message to the second communication device, where the second communication device may return a corresponding data set according to the indication or request message.

The S1110 may include: directly or indirectly receiving the data set from the second communication device.

Exemplarily, the data set includes at least one of the following data: a measurement result and location information; a measurement result and indication information; a measurement result, location information, and indication information; a measurement result; the measurement result includes a measurement result of a positioning reference signal; the location information includes location information of a measuring device and/or the location information of a measured device; and the indication information is used to indicate that a measurement path for obtaining the measurement result is a line-of-sight (LoS) or a non-line-of-sight (NLoS).

In some embodiments of the present disclosure, the positioning reference signal includes but is not limited to an uplink positioning reference signal and/or a downlink reference positioning signal. The positioning reference signal may include: an uplink positioning reference signal (Surrounding Reference Signal, SRS) and/or a downlink positioning reference signal (Positioning reference signal, PRS).

In short, the positioning reference signal may be a reference signal dedicated to positioning, and the positioning reference signal may be sent and/or received by the base station. By sending and receiving the positioning reference signal, at least the relative distance between the measured object and the access network device that transmits the positioning reference signal may be obtained.

The measurement result may include: a measurement value obtained by measuring the positioning reference signal.

The location information includes: location information of the measuring device involved in the positioning measurement and/or location information of the measured device preliminarily calculated by the measuring device. The location information includes but is not limited to absolute location information such as longitude and latitude and/or relative location information between the measured device and the measuring device.

The measuring device and the measured device can both be UE, relay node or mobile transmission reception point (TRP).

The LOS is an unobstructed measurement path; the NLos is an obstructed measurement path. Exemplarily, the measurement result may include at least one of the following: a Reference Signal Time Difference (RSTD); a Relative Time of Arrival (RTOA); an Angle of Arrival (AOA); an Angle-of-Departure (AoD); a Time of Arrival (TOA); a Reference Signal Received Power (RSRP); a Reference Signal Received Path Power (RSRPP); a Channel impulse response (CIR); an Observation arrival time difference (OATD).

The above are merely examples of the measurement results, and the specific implementation is not limited to the above examples.

That is, the data set may include the measurement result alone, or may include the measurement result and information related to the measurement status. The related information includes location information and/or indication information.

For example, the location information may be location information of the measuring UE and/or the measured UE.

The indication information of whether the measurement path is a line-of-sight or a non-line-of-sight may include: LoS information or NoLS information.

In some embodiments of the present disclosure, the measurement result includes: a first measurement result and/or a second measurement result; where the second measurement result is different from the first measurement result.

Exemplarily, the first measurement result may be directly used to calculate the location information of the measured object; and the second measurement result may be indirectly used to calculate the location information of the measured object.

As another example, the first measurement result may be used to calculate the location information of the measured object alone, while the second measurement result requires other information assistance to calculate the location information of the measured object.

The above are merely examples of the first measurement result and the second measurement result, and the specific implementation is not limited to the above examples.

The measured object includes but is not limited to: mobile devices such as UE and/or relay device.

In some embodiments of the present disclosure, the second measurement result includes at least one of the following: an RSRP obtained by measuring the positioning reference signal; a PRSPP obtained by measuring the positioning reference signal; and/or a CIR obtained by measuring the positioning reference signal.

The first measurement result may be other measurement values other than the RSPR, PRSPP and CIR. The other measurement values may include: RSTD, RTOA, AOA, TOA and/or OATD, etc.

It should be noted that the measurement result of the aforementioned embodiments may include: a first type measurement result and/or a second type measurement result.

In some embodiments of the present disclosure, the data set has description information, and the description information indicates at least one of the following: a type of data set, a data format, an amount of data, a collection scene, a collection location, and a reference signal configuration corresponding to the data set.

The description information may indicate one or more attributes (characteristics) of the data set.

Through the description information, the first communication device may indicate the attribute or characteristic of the data set it wants to the second communication device, and the first communication device can know the attribute or characteristic of the data set provided by the second communication device.

For example, the type of the data set may be used to indicate the specific type of one or more positioning-related data contained in the data set. Different types of data sets may have different positioning precisions or different accuracy.

Some types of data sets require specific preprocessing before AI/ML model training, while other types of data sets do not require it.

Different data may adopt different data formats, such as a numerical storage format, a vector storage format, and/or a matrix storage format. The matrix storage format may include: a two-dimensional matrix storage format, a three-dimensional matrix storage format, and/or a higher-dimensional data storage format, which are only examples of the data format.

The amount of data may limit the maximum amount of data of one data set, or the total amount of data of one or more received data sets.

In some embodiments of the present disclosure, if there are multiple data sets, the amount of data may also be the average amount of data of the multiple data sets.

The collection location may be the location information of the measuring device and/or the area information of the area where the measuring device is located. The area information may include but is not limited to a cell, a tracking area or a notification area.

The reference signal configuration may include at least one of the following: a time domain resource configuration of a reference signal; a frequency domain resource configuration of a reference signal; and/or a type configuration of the reference signal, for example, the reference signal related to positioning may include: an uplink positioning reference signal and/or a downlink positioning reference signal.

The collection scene may be differentiated according to the purpose, building type and/or height of the site for collecting the data set.

For example, the collection scenes may be divided into: an underground scene and/or an above-ground scene, an open-air scene and/or a blocked scene.

For another example, the collection scenes may be divided into: a high-altitude scene, a ground scene, a seabed scene or an underground scene, etc.

For another example, the collection scenes may be divided into: a crowd hotspot scene and a non-crowd hotspot scene. The crowd hotspot scene may include: a shopping mall, a gymnasium, a school, and/or a residential area with high floor area ratio.

The above are only examples of the above information, and the specific implementation is not limited to the above examples.

As shown in FIG. 2B, an embodiment of the present disclosure provides an information processing method, which is performed by the first communication device, and the method includes: S1210: sending a request message to a second communication device, where the request message is used to request the data set from the second communication device.

In S1220: a data set returned by the second communication device based on the request message is received, where the data set is used by the AI/ML model at least for positioning.

If the first communication device wants to obtain a data set, it can send a request message to the corresponding second communication device. The request message includes but is not limited to a Long Term Evolution Positioning Protocol (LPP) message or a New Radio Positioning Protocol a (NRPPa) message to send the request message.

In some embodiments of the present disclosure, when the first communication device is an LMF and the second communication device is a UE, the request message may be an LPP message.

In some embodiments of the present disclosure, when the first communication device is an LMF and the second communication device is a gNB, the request message is an NRPPa message.

If the request message is sent using the LPP message, the data set may also be returned to the first communication device based on the LPP message.

If the request message is sent using the NRPPa message, the data set may also be returned to the first communication device based on the NRPPa message. In one embodiment, the request message includes the description information. If the request message includes the description information, the second communication device may return the data set to the first communication device according to the description information.

In some embodiments of the present disclosure, the first communication device may request data sets with different description information from different second communication devices. In this case, the second communication device may return corresponding description information to the first communication device while sending the data set to the first communication device, thereby facilitating the first communication device to check and compare.

In some embodiments of the present disclosure, receiving the data set from the second communication device includes: receiving the data set provided by the second communication device according to the description information.

As another example, if the second communication device actively reports a data set, the second communication device may send the data set together with the description information to the first communication device. Similarly, the first communication device may simultaneously receive the data set and the description information of the data set from the second communication device.

In some embodiments of the present disclosure, the first communication device is a location management function (LMF), and the second communication device is: a user equipment (UE) and/or an access network device; or the first communication device is a UE, and the second communication device is an LMF and/or an access network device; or the first communication device is an access network device, and the second communication device is: UE and/or LMF; or the first communication device is an operation administration and maintenance (OAM), and the second communication device is: an access network device and/or an LMF; or the first communication device is a network data analysis function (NWANF), and the second communication device is any one of the following: an access network device, OAM, LMF, UE.

As shown in FIG. 2C, an embodiment of the present disclosure provides an information processing method, where the method is performed by a first communication device, and the second communication device is a UE. The method includes the following steps.

In S1310: data capability information sent by a UE is received; where the data capability information indicates whether the UE has a capability to provide a data set.

In S1320: a request message is sent to a UE having the capability to provide the data set, where the request message is used to request the data set from the second communication device.

In S1330: a data set is received from the UE having the capability to provide the data set.

Some UEs have the capability to provide the data set, while some UEs do not have the capability to provide the data set. For example, a UE with a small storage capacity or a UE with poor data collection and other processing capabilities or a UE with a short standby time may not have the capability to provide the data set. In view of this, if the second communication device includes a UE, it is necessary to know the data set capability information corresponding to the UE in advance, and the data set can be only received and/or provided from the UE with the capability to provide the data set.

In an embodiment of the present disclosure, if the first communication device sends data capability request information to the UE, which will provide the data set, the UE receiving the data capability request information is instructed to report the data capability information.

If there is a UE with data providing capability, the UE may be instructed to provide the data set to the first communication device.

In some embodiments of the present disclosure, the method further includes: sending data capability request information to the UE, where the data capability request information may instruct the UE to send the aforementioned data capability information to the first communication device.

In some embodiments of the present disclosure, the data capability information of the UE is further used to indicate at least one of the following: a type of a data set supported by the UE, a data format supported by the UE, an amount of data supported by the UE, a collection scene supported by the UE, a collection location supported by the UE, and a reference signal configuration corresponding to the data set supported by the UE.

Different UEs have different capabilities, so the attribute related to the providing capability of data set may include any one or more of the above.

For example, some UEs do not support the transmission of the uplink positioning reference signal, while some UEs do have sufficient power consumption and transmission power to transmit the uplink positioning reference signal.

In some embodiments of the present disclosure, the type of the data set is one of the following: a first type, a data set with a data element being a measurement result and a location information; where the measurement result is a measurement result of a positioning reference signal; where the location information includes: location information of a measuring device and/or location information of a measured device; a second type, a data set with the data element being the measurement result and indication information; where the measurement result is a measurement result of a positioning reference signal; the indication information indicates that a measurement path for obtaining the measurement result is a line-of-sight (LoS) or a non-line-of-sight (NLoS); or a third type, a data set with the data element being the measurement result.

Different types of data sets can contain different types of data elements.

In some embodiments of the present disclosure, the collection scene is one of the following: an outdoor scene; an indoor scene; a predetermined building scene; or a predetermined use scene.

Exemplarily, the indoor scene is a scene inside a building, and the outdoor scene is a scene outside the building.

Exemplarily, the predetermined building scene may include, but is not limited to: a ground and/or underwater tunnel scene, a subway scene, a highway scene, a railway scene, etc.

Also exemplarily, the predetermined use scene may include, but is not limited to: a factory scene, a square scene, a green space scene, a park scene, a store scene, a street scene, a school scene and/or a library scene, etc.

The above are just examples of various scenes, and the specific implementation is not limited to the above examples.

In some embodiments of the present disclosure, the collection location includes at least one of the following: a cell identifier, indicating a cell corresponding to a place where the data set is generated; a base station identifier, indicating a base station corresponding to the place where the data set is generated; a transmission reception point identifier, indicating a transmission reception point corresponding to the place where the data set is generated; and/or UE location information, indicating a UE location when the UE collects data.

The cell identifier may include but is not limited to a physical cell identifier.

The base station identifier may include an eNB identifier and/or a gNB identifier.

One base station may have multiple transmission reception points, and different transmission reception points are distributed at different locations. Therefore, different transmission reception point identifiers may also represent different locations.

The UE location indicated by the UE location information may be location information obtained by satellite positioning or location information obtained based on the Location Management Function (LMF). Adding the collection location in the description information may instruct the second communication device to collect the data set at a specific location.

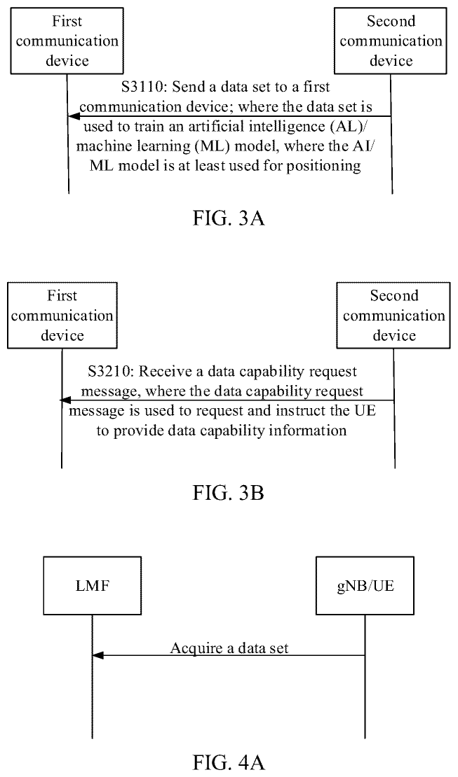

As shown in FIG. 3A, an embodiment of the present disclosure provides an information processing method, which is performed by a second communication device, and the method includes the following steps.

In S3110: a data set is sent to a first communication device; where the data set is used to train an artificial intelligence (AL)/machine learning (ML) model, where the AI/ML model is at least used for positioning.

The second communication device may be a network device and/or a UE.

The second communication device may actively send the data set to the first communication device, or send the data set to the first communication device based on a request message from the first communication device.

The data set may be used to train an AI/ML model for positioning. After being trained, the AI/ML model can at least be used to calculate location information, for example, it can output absolute location information and/or relative location information. After the AI/ML model is trained, it can at least be used to process the input data set to obtain the location information that meets the accuracy requirement and/or delay requirement.

Similarly, if the first communication device is UE, then the second communication device is LMF and/or the access network device; or, if the first communication device is the access network device, then the second communication device is: UE and/or LMF; or, if the first communication device is operation administration and maintenance (OAM), then the second communication device is: the access network device and/or LMF; or, if the first communication device is network data analysis function (NWANF), then the second communication device is: the access network device, OAM, LMF and/or UE.

In some embodiments of the present disclosure, the data set includes at least one of the following data: a measurement result and location information; a measurement result and indication information; a measurement result, location information, and indication information; and/or a measurement result. The measurement result includes a measurement result of the positioning reference signal; the location information includes the location information of a measuring device and/or the location information of a measured device; and the indication information is used to indicate that a measurement path for obtaining the measurement result is a line-of-sight (LoS) or a non-line-of-sight (NLoS).

In some embodiments of the present disclosure, the positioning reference signal includes but is not limited to an uplink positioning reference signal and/or a downlink reference positioning signal. The positioning reference signal may include: an uplink positioning reference signal (Surrounding Reference Signal, SRS) and/or a downlink positioning reference signal (PRS). In short, the positioning reference signal may be a reference signal dedicated to positioning, and the positioning reference signal may be sent and/or received by a base station. By sending and receiving the positioning reference signal, at least the relative distance between the measured object and the access network device that transmits the positioning reference signal can be obtained.

The measurement result is a measurement value obtained by measuring the positioning reference signal.

The location information includes: location information of the measuring device involved in the positioning measurement and/or location information of the measured device preliminarily calculated by the measuring device. The location information includes but is not limited to absolute location information such as longitude and latitude and/or relative location information between the measured device and the measuring device.

The measuring device and the measured device can both be UE, relay node or mobile transmission reception point (TRP).

The LOS is an unobstructed measurement path; the NLos is an obstructed measurement path. Exemplarily, the measurement result may include at least one of the following: a Reference Signal Time Difference (RSTD); a Relative Time of Arrival (RTOA); an Angle of Arrival (AOA); an Angle-of-Departure (AoD); a Time of Arrival (TOA); a Reference Signal Received Power (RSRP); a Reference Signal Received Path Power (RSRPP); a Channel impulse response (CIR); and/or an Observation arrival time difference (OATD).

The above are merely examples of the measurement result, and the specific implementation is not limited to the above examples.

That is, the data set may include the measurement result alone, or may include the measurement result and information related to the measurement status.

For example, the location information of the UE is measured. The indication information of whether the measured path is a line-of-sight or a non-line-of-sight may include: LoS information or NoLS information.

In some embodiments of the present disclosure, the measurement result includes: a first measurement result and/or a second measurement result; where the second measurement result is different from the first measurement result.

Exemplarily, the first measurement result may be directly used to calculate the location information of the measured object; and the second measurement result may be indirectly used to calculate the location information of the measured object.

As another example, the first measurement result can be used to calculate the location information of the measured object alone, while the second measurement result requires other information assistance to calculate the location information of the measured object.

The above are merely examples of the first measurement result and the second measurement result, and the specific implementation is not limited to the above examples.

The measured object includes but is not limited to: mobile devices such as UE and/or relay device.

In some embodiments of the present disclosure, the second measurement result includes at least one of the following: RSRP obtained by measuring the positioning reference signal; PRSPP obtained by measuring the positioning reference signal; CIR obtained by measuring the positioning reference signal. The first measurement result may be other measurement values other than the RSPR, PRSPP and CIR. The other measurement values may include: RSTD, RTOA, AOA, TOA and/or OATD, etc. It is worth noting that the measurement result of the aforementioned embodiments may include: a first type measurement result and/or a type category measurement result.

In some embodiments of the present disclosure, the data set has description information, and the description information indicates at least one of the following: a type of data set, a data format, an amount of data, a collection scene, a collection location, and a reference signal configuration corresponding to the data set.

The description information may indicate one or more attributes (characteristics) of the data set.

Through the description information, the first communication device can indicate the attribute or characteristic of the data set it wants to the second communication device, and the first communication device can know the attribute or characteristic of the data set provided by the second communication device.

For example, the type of the data set may be used to indicate: the specific type of one or more positioning-related data contained in the data set; different types of data sets may have different positioning precisions or different accuracy.

Some types of data sets require specific preprocessing before AI/ML model training, while other types of data sets do not require this.

Different data may adopt different data formats, such as a numerical storage format, a vector storage format, and/or a matrix storage format. The matrix storage format may include: a two-dimensional matrix storage format, a three-dimensional matrix storage format, and/or a higher-dimensional data storage format, which are only examples of the data format.

The amount of data may limit the maximum amount of data of one data set, or the total amount of data of one or more received data sets.

In some embodiments of the present disclosure, if there are multiple data sets, the amount of data may also be the average amount of data of the multiple data sets.

The collection location may be the location information of the measuring device and/or the area information of the area where the measuring device is located. The area information may include but is not limited to a cell, a tracking area or a notification area, etc.

The reference signal configuration may include at least one of the following: a time domain resource configuration of a reference signal; a frequency domain resource configuration of a reference signal; and/or a type configuration of the reference signal, for example, the reference signal related to positioning may include: an uplink positioning reference signal and/or a downlink positioning reference signal.

The collection scenes may be differentiated according to the purpose, building type and/or height of the collection site of the data set.

For example, the collection scenes may be divided into: an underground scene and/or an above-ground scene, an open-air scene and/or a blocked scene.

For another example, the collection scenes may be divided into: a high-altitude scene, a ground scene, a seabed scene or an underground scene, etc.

For another example, the collection scenes may be divided into: a crowd hotspot scene and a non-crowd hotspot scene. The crowd hotspot scene may include: a shopping mall, a gymnasium, a school, and/or a residential area with high floor area ratio.

The above are only examples of the above information, and the specific implementation is not limited to the above examples. As shown in FIG. 3B, the embodiment of the present disclosure provides an information processing method, which is performed by a second communication device, and the second communication device is a UE, and the method includes the following steps.

In S3210: a data capability request message is received, where the data capability request message is used to request and instruct the UE to provide data capability information.

If the first communication device sends data capability request information to the UE which provides the data set, the UE receiving the data capability request information is instructed to report the data capability information. If there is a UE with data providing capability, the UE can be instructed to provide the data set to the first communication device. Exemplarily, the data capability information of the UE is also used to indicate at least one of the following: a type of data set supported by the UE, a data format supported by the UE, an amount of data supported by the UE, a collection scene supported by the UE, a collection location supported by the UE, and a reference signal configuration corresponding to the data set supported by the UE.

Different UEs have different capabilities, so the attributes related to the providing capability of data set may include any one or more of the above.

For example, some UEs do not support the transmission of uplink positioning reference signals, while some UEs do have sufficient power consumption and transmission power to transmit uplink positioning reference signals.

It is worth noting that the above step S3210 may be an optional step. For example, the first communication device is a network device, and the network device may determine whether the corresponding UE has the capability to provide a data set based on the contract data or model data of the UE. Alternatively, in some scenes, the first communication device may directly assume that a specific UE has the capability to provide a data set.

Exemplarily, the type of the data set is one of the following: a first type, a data set with the data element being a measurement result and location information; where the measurement result is a measurement result of a positioning reference signal; where the location information includes: location information of a measuring device and/or location information of a measured device; a second type, a data set with the data element being the measurement result and indication information; where the measurement result is a measurement result of a positioning reference signal; the indication information indicates that the measurement path for obtaining the measurement result is a line-of-sight (LoS) or a non-line-of-sight (NLoS); or a third type, a data set with the data element being the measurement result.

Exemplarily, the collection scene is one of the following: an outdoor scene; an indoor scene; a predetermined building scene; or a predetermined use scene.

Exemplarily, the indoor scene is a scene inside a building, and the outdoor scene is a scene outside the building.

Exemplarily, the predetermined building scene may include, but is not limited to: a ground and/or underwater tunnel scene, a subway scene, a highway scene, a railway scene, etc.

Also exemplarily, the predetermined use scene may include, but is not limited to: a factory scene, a square scene, a green space scene, a park scene, a store scene, a street scene, a school scene and/or a library scene, etc.

The above are just examples of various scenes, and the specific implementation is not limited to the above examples.

In some embodiments of the present disclosure, the collection location includes at least one of the following: a cell identifier, indicating a cell corresponding to a place where the data set is generated; a base station identifier, indicating a base station corresponding to the place where the data set is generated; a transmission reception point identifier, indicating a transmission reception point corresponding to the place where the data set is generated; and/or UE location information, indicating a UE location when the UE collects data.

In some embodiments of the present disclosure, the reference signal configuration includes: a downlink positioning reference signal (PRS) configuration; a Surrounding Reference Signal (SRS) configuration.

The cell identifier may include but is not limited to a physical cell identifier.

The base station identifier may include an eNB identifier and/or a gNB identifier.

One base station may have multiple transmission reception points, and different transmission reception points are distributed at different locations. Therefore, different transmission reception point identifiers may also represent different locations.

The UE location indicated by the UE location information may be location information obtained through satellite positioning or location information obtained based on the Location Management Function (LMF).

Adding the collection location in the description information may instruct the second communication device to collect a data set at a specific location.

The embodiments of the present disclosure provide a method for acquiring a data set, where the data set is used to train an AI/ML model for positioning, including the following scenes.

### Scene 1

LMF trains the AI/ML model using the data set.

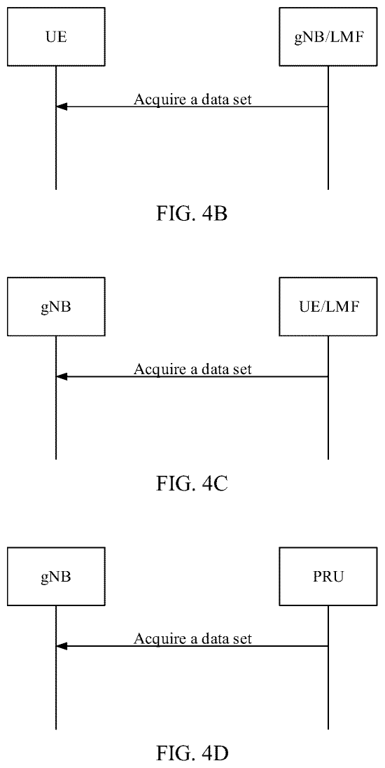

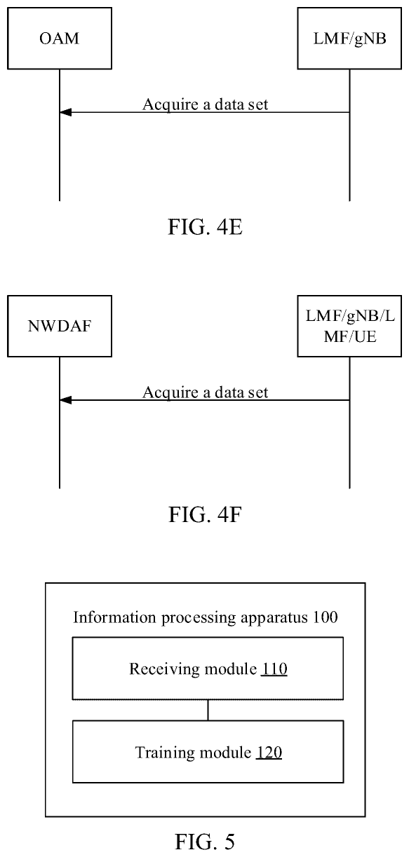

As shown in FIG. 4A, the LMF obtains a data set from the UE.
a. The UE's capability to provide a data set (LPP provide capability) may include at least one of the following: a type of supported data set, for example, a data set of the measurement result (RSRP/RSRPP/TOA/RSTD/CIR) and location, and a result of the measurement result (RSRP/RSRPP/TOA/RSTD/CIR) and LoS information, or a result of the measurement result (RSRP/RSRPP/TOA/RSTD/CIR) and NLoS information; LoS information indicating that the measured path is a line-of-sight, NLoS information indicating that the measured path is a non-line-of-sight; a format and size (i.e. amount of data) of the supported data set; a scene corresponding to the supported data set, for example, the scene corresponding to the data set is indoor, outdoor, factory and other scenes.
b. The UE can provide the above capability based on the request of the LMF, that is, the LMF requests the capability of the UE to provide the data set. The information indicating whether the UE has the capability to provide the data set can be carried by the LPP message.
c. LMF requests UE to provide a data set (LPP request location information), which may include at least one of the following: a type of data set, such as a data set of the measurement result (RSRP/RSRPP/TOA/RSTD/CIR) and location, or a result of the measurement result (RSRP/RSRPP/TOA/RSTD/CIR) and LoS information, or a result of the measurement result (RSRP/RSRPP/TOA/RSTD/CIR) and NLoS information; a format and size of the data set; a scene corresponding to the data set; a PRS configuration corresponding to the data set; and/or a cell identifier (cell ID) or transmission reception point identifier (TRP ID) corresponding to the data set.
d. The UE provides the above data set based on the request of the LMF; alternatively, the LMF obtains the data set from the gNB.

### Scene 2

LMF trains the AI/ML model using a data set.

As shown in FIG. 4A, LMF acquires the data set from the gNB.
a. LMF requests the gNB to provide a data set, where the description information of the data set may include at least one of the following: a type of data set, for example, a data set of measurement result and location information; the measurement result may be RSRP, RSRPP, TOA, RSTD and/or CIR obtained by measuring an uplink positioning reference signal, and/or the result of the measurement result and LoS information or the result of the measurement result and NLoS information. The location information may include information of a positioning reference unit (PRU); the measurement result may be RSRP, RSRPP, TOA, AoA and/or CIR obtained by measuring the positioning reference signal; the format and size of the data set; the scene corresponding to the data set; for example, the scene corresponding to the data set is indoor, outdoor, factory, etc.; uplink positioning reference signal configuration corresponding to the data set; UE identifier corresponding to the data set.
b. gNB provides the data set based on the request of LMF.

### Scene 3

UE trains the AI/ML model using a data set.

As shown in FIG. 4B, the UE obtains a data set from the LMF.

Exemplarily, a. UE requests LMF to provide a data set, and the description information of the data set may indicate at least one of the following: a type of data set; a format, size of the data set; a scene corresponding to the data set; a PRS configuration corresponding to the data set; a cell ID or TRP ID corresponding to the data set.

The description information may be carried in the LPP request assistance information.

LMF provides a data set to UE. Similarly, the data set may be carried in the LPP provide assistance information.

### Scene 4

UE trains the AI/ML model using a data set.

As shown in FIG. 4B, the UE obtains the data set from the gNB.
a. The UE requests the gNB to provide a data set. The description information of the data set may indicate at least one of the following: a type of data set; a format, size of data set; a scene corresponding to the data set; a PRS configuration corresponding to the data set; a cell ID or TRP ID corresponding to the data set.

The description information of the data set may be carried in the LPP request assistance information.
b. The gNB provides a data set to the UE, and the data set may be carried in the LPP request assistance information (LPP provide assistance information).

The UE can also actively report the data set.

### Scene 5

gNB trains the AI/ML model using a data set.

As shown in FIG. 4C, the gNB acquires the data set from the LMF.

Exemplarily, the gNB requests the LMF to provide a data set, and the description information of the data set may indicate at least one of the following: a type of data set; a format, size of data set; a scene corresponding to the data set; an SRS configuration corresponding to the data set; a cell ID or TRP ID corresponding to the data set.
b. LMF provides the data set to the gNB, for example, based on the NRPPa message.

The description information of the data set provided by the LMF to the gNB may indicate at least one of the following: a type of data set, such as a result of measurement result (RSRP/RSRPP/TOA/AoA/CIR) and LoS information, or a result of measurement result (RSRP/RSRPP/TOA/AoA/CIR) and NLoS information; a scene corresponding to the data set; for example, the scene corresponding to the data set is indoor, outdoor, factory, etc.; an uplink positioning reference signal configuration corresponding to the data set; a base station identifier corresponding to the data set, for example, TRP ID, cell ID.

### Scene 6

gNB trains the AI/ML model using a data set.

As shown in FIG. 4D, the gNB obtains a data set from a PRU. The PRU may be a special UE whose current location is known and has a positioning-related function. The gNB requests the PRU to provide a data set.

The PRU provides a data set. Exemplarily, the data set provided by the PRU may include location information of the PRU and corresponding positioning measurement result.

### Scene 7

OAM trains the AI/ML model using a data set.

Referring to FIG. 4E, OAM may obtain the data set from gNB or LMF.
a. OAM requests the gNB or LMF to provide a data set. The description information of the data set may indicate at least one of the following: a type of data set; a format, size of data set; a scene corresponding to the data set; an SRS configuration or PRS configuration corresponding to the data set; a cell ID or TRP ID corresponding to the data set.
b. gNB or LMF provides the data set based on the request of OAM.

### Scene 8

NWDAF trains the AI/ML model using a data set.

Referring to FIG. 4F, NWDAF obtains a data set directly or indirectly from gNB or OAM or LMF or UE.
a. The NWDAF directly or indirectly requests the gNB, OAM, LMF or UE to provide a data set. The description information of the data set may indicate at least one of the following: a type of data set; a format, size of data set; a scene corresponding to the data set; an SRS configuration or PRS configuration corresponding to the data set; a cell identifier (cell ID) or transmission reception point identifier (transmission reception point Identifier, TRP ID) corresponding to the data set.
b. gNB or OAM or LMF or UE provides the data set based on the request of NWDAF.

As shown in FIG. 5, an embodiment of the present disclosure provides an information processing apparatus 100, where the apparatus 100 includes: a receiving module 110 and a training module 120.

The receiving module 110 is configured to receive a data set from a second communication device.

The training module 120 is configured to train an artificial intelligence (AI)/machine learning (ML) model using the data set, where the AI/ML model is at least used for positioning.

The information processing apparatus may be the aforementioned first communication device.

The first communication device may be a network device or a UE.

The second communication device may be any network device or UE different from the aforementioned first communication device.

It can be understood that the data set includes at least one of the following data: a data set of a measurement result and location information; where the measurement result is a measurement result of a positioning reference signal; where the location information includes: location information of a measuring device and/or location information of a measured device; a data set of the measurement result and indication information; where the measurement result is a measurement result of a positioning reference signal; the indication information indicates that a measurement path for obtaining the measurement result is a line-of-sight (LoS) or a non-line-of-sight (NLoS); a data set of the measurement result.

It can be understood that the measurement result includes: a first measurement result and/or a second measurement result; where the second measurement result is different from the first measurement result; the second measurement result includes at least one of the following: a reference signal received power (RSRP) obtained by measuring the positioning reference signal; a reference signal received path power (PRSPP) obtained by measuring the positioning reference signal; a channel impulse response (CIR) obtained by measuring the positioning reference signal.

It can be understood that the data set has description information, and the description information indicates at least one of the following: the type of data set, the data format, the amount of data, the collection scene, the collection location, and the reference signal configuration corresponding to the data set.

It can be understood that the method further includes: sending a request message to the second communication device, where the request message is used to request the data set from the second communication device.

It can be understood that the request message includes description information of the data set.

It can be understood that the receiving module 110 is configured to receive the data set provided by the second communication device according to the description information.

It can be understood that the first communication device is a location management function (LMF), and the second communication device is: a user equipment (UE) and/or an access network device; or the first communication device is a UE, and the second communication device is a LMF and/or an access network device; or the first communication device is an access network device, and the second communication device is: UE and/or LMF; or the first communication device is an operation administration and maintenance (OAM), and the second communication device is: an access network device and/or a LMF; or the first communication device is a network data analysis function (NWANF), and the second communication device is any one of the following: an access network device, OAM, LMF, UE.

It can be understood that the data capability information of the UE is also used to indicate at least one of the following: the type of data set supported by the UE, the data format supported by the UE, the amount of data supported by the UE, the collection scene supported by the UE, the collection location supported by the UE, and the reference signal configuration corresponding to the data set supported by the UE. It can be understood that the type of the data set is one of the following: a first type, a data set with the data element being a measurement result and location information; where the measurement result is a measurement result of a positioning reference signal; where the location information includes: location information of a measuring device and/or location information of a measured device; a second type, a data set with the data element being a measurement result and indication information; where the measurement result is a measurement result of a positioning reference signal; the indication information indicates that the measurement path for obtaining the measurement result is a line-of-sight (LoS) or a non-line-of-sight (NLoS); a third type, a data set with the data element being the measurement result.

It can be understood that the collection scene is one of the following: an outdoor scene; an indoor scene; a predetermined building scene; a predetermined use scene.

It can be understood that the collection location includes at least one of the following: a cell identifier, indicating the cell corresponding to the place where the data set is generated; a base station identifier, indicating the base station corresponding to the place where the data set is generated; a transmission reception point identifier, indicating the transmission reception point corresponding to the place where the data set is generated; UE location information, indicating the UE location when the UE collects data.

It can be understood that the reference signal configuration includes: a downlink positioning reference signal (PRS) configuration; and a Surrounding Reference Signal (SRS) configuration.

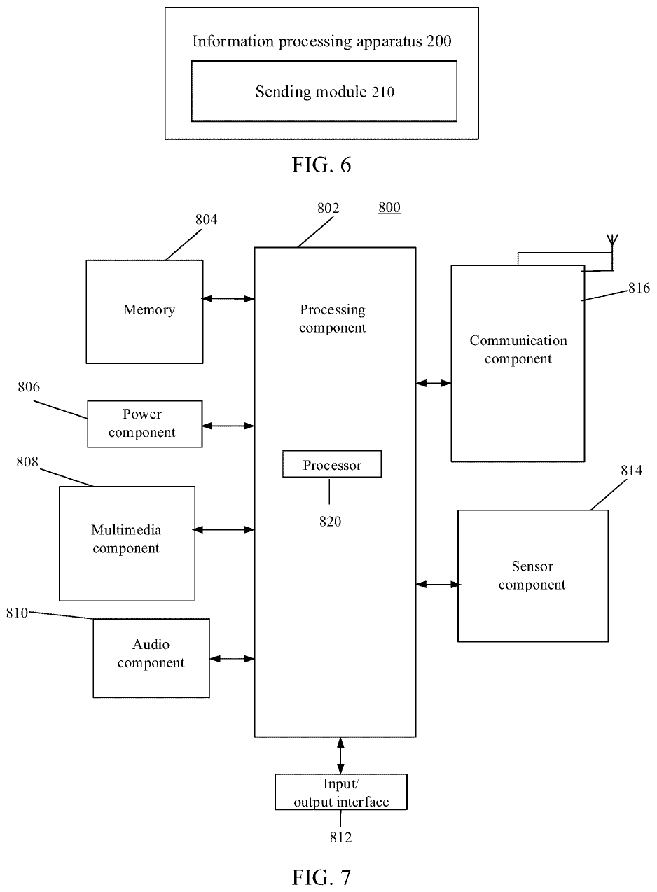

As shown in FIG. 6, an embodiment of the present disclosure provides an information processing apparatus 200, where the apparatus 200 includes a sending module 210, configured to send a data set to a first communication device; where the data set is used to train an artificial intelligence (AL)/machine learning (ML) model, where the AI/ML model is at least used for positioning.

The information processing apparatus 200 may include a second communication device.

The information processing apparatus 200 also includes: a storage module; the storage module is connected to the sending module 210, and is used to store the data set.

It can be understood that the data set includes at least one of the following data: a data set of a measurement result and location information; where the measurement result is a measurement result of a positioning reference signal; where the location information includes: location information of a measuring device and/or location information of a measured device; a data set of a measurement result and indication information; where the measurement result is a measurement result of a positioning reference signal; the indication information indicates that the measurement path for obtaining the measurement result is a line-of-sight (LoS) or a non-line-of-sight (NLoS); a data set of the measurement result.

It can be understood that the measurement result includes: a first measurement result and/or a second measurement result; where the second measurement result is different from the first measurement result. The second measurement result includes at least one of the following: a reference signal received power (RSRP) obtained by measuring the positioning reference signal; a reference signal received path power (PRSPP) obtained by measuring the positioning reference signal; a channel impulse response (CIR) is obtained by measuring the positioning reference signal.

It can be understood that the data set has description information, and the description information indicates at least one of the following: the type of data set, the data format, the amount of data, the collection scene, the collection location, and the reference signal configuration corresponding to the data set.

An embodiment of the present disclosure provides an information processing system, which includes: a first communication device and a second communication device. The first communication device is configured to receive a data set from the second communication device and train an artificial intelligence (AI)/machine learning (ML) model using the data set, where the AI/ML model is at least used for positioning. The second communication device is configured to send a data set to the first communication device, where the data set is used for training an artificial intelligence (AL)/machine learning (ML) model, where the AI/ML model is at least used for positioning.

It can be understood that the data set includes at least one of the following data: a measurement result and location information; a measurement result and indication information; a measurement result, location information, and indication information; a measurement result. The measurement result includes a measurement result of a positioning reference signal; the location information includes location information of a measuring device and/or location information of a measured device; and the indication information is used to indicate that a measurement path for obtaining the measurement result is a line-of-sight (LoS) or a non-line-of-sight (NLoS).

It can be understood that the measurement result includes: a first measurement result and/or a second measurement result; where the second measurement result is different from the first measurement result.

In some embodiments of the present disclosure, the second measurement result includes at least one of the following: a reference signal received power (RSRP) obtained by measuring the positioning reference signal; a reference signal received path power (PRSPP) obtained by measuring the positioning reference signal; a channel impulse response (CIR) is obtained by measuring the positioning reference signal.

It can be understood that the method further includes: sending a request message to the second communication device, where the request message is used to request the data set from the second communication device.

It can be understood that the request message includes description information.

It can be understood that the data set has description information, and the description information indicates at least one of the following: the type of data set, the data format, the amount of data, the collection scene, the collection location, and the reference signal configuration corresponding to the data set.

It can be understood that receiving the data set from the second communication device includes: receiving the data set provided by the second communication device according to the description information.

It can be understood that the first communication device is a location management function (LMF), and the second communication device is: a user equipment (UE) and/or an access network device; or the first communication device is a UE, and the second communication device is a LMF and/or an access network device; or the first communication device is an access network device, and the second communication device is: UE and/or LMF; or the first communication device is an operation administration and maintenance (OAM), and the second communication device is: an access network device and/or a LMF; or the first communication device is a network data analysis function (NWANF), and the second communication device is any one of the following: access network device, OAM, LMF, UE.

It can be understood that the first communication device is not a UE, and the second communication device is a UE; the method further includes: receiving data capability information sent by the UE; where the data capability information indicates whether the UE has the capability to provide the data set.

It can be understood that the method further includes: the first communication device sending a data capability request message to the UE, where the data capability request message is used to request the UE to provide the data capability information; and the second communication device receiving the data capability request message. The data capability information of the UE is also used to indicate at least one of the following: the type of data set supported by the UE, the data format supported by the UE, the amount of data supported by the UE, the collection scene supported by the UE, the collection location supported by the UE, and the reference signal configuration corresponding to the data set supported by the UE.

It can be understood that the type of the data set is one of the following: the first type, the data set with the data element being a measurement result and location information; where the measurement result is a measurement result of a positioning reference signal; where the location information includes: location information of a measuring device and/or location information of a measured device; the second type, a data set with the data element being a measurement result and indication information; where the measurement result is a measurement result of a positioning reference signal; the indication information indicates that the measurement path for obtaining the measurement result is a line-of-sight (LoS) or a non-line-of-sight (NLoS); the third type, a data set with the data element being the measurement result.

It can be understood that the collection scene is one of the following: outdoor scene; indoor scene; predetermined building scene; predetermined use scene.

It can be understood that the collection location includes at least one of the following: a cell identifier, indicating the cell corresponding to the place where the data set is generated; a base station identifier, indicating the base station corresponding to the place where the data set is generated; a transmission reception point identifier, indicating the transmission reception point corresponding to the place where the data set is generated; UE location information, indicating the UE location when the UE collects data.

It can be understood that the reference signal configuration includes: a downlink positioning reference signal (PRS) configuration; and a Surrounding Reference Signal (SRS) configuration.

The present disclosure provides a communication device, including: a memory for storing an executable instruction of a processor; the processor, respectively connected to the memory; where the processor is configured to execute the information processing method provided by any of the aforementioned technical solutions.

The processor may include various types of storage media, which are non-transitory computer storage media that can continue to remember information stored thereon after the communication device loses power.

Here, the communication device includes: the aforementioned first communication device and/or second communication device. The first communication device and the second communication device may both include: a network device and/or UE.

The processor may be connected to the memory via a bus or the like, and is used to read the executable program stored in the memory, for example, at least one of the methods shown in FIGS. 2A to 2C, 3A to 3B, and 4A to 4C.

The present disclosure provides a communication system, where the communication system includes: a first communication device, configured to execute the information processing method performed by the first communication device, and a second communication device, configured to execute the information processing method executed by the second communication device.

FIG. 7 is a block diagram of a UE 800 according to an exemplary embodiment. For example, the UE 800 may be a mobile phone, a computer, a digital broadcast user equipment, a messaging device, a game console, a tablet, a medical device, a fitness device, a personal digital assistant, etc.

Referring to FIG. 7, UE 800 may include one or more of the following components: a processing component 802, a memory 804, a power component 806, a multimedia component 808, an audio component 810, an input/output (I/O) interface 812, a sensor component 814, and a communication component 816.

The processing component 802 generally controls the overall operation of the UE 800, such as operations associated with display, phone calls, data communications, camera operations, and recording operations. The processing component 802 may include one or more processors 820 to execute instructions to generate all or part of the steps of the above-described method. In addition, the processing component 802 may include one or more modules to facilitate interaction between the processing component 802 and other components. For example, the processing component 802 may include a multimedia module to facilitate interaction between the multimedia component 808 and the processing component 802.

The memory 804 is configured to store various types of data to support operations on the UE 800. Examples of such data include instructions for any application or method operating on the UE 800, contact data, phone book data, messages, pictures, videos, etc. The memory 804 may be implemented by any type of volatile or non-volatile storage device or a combination thereof, such as static random access memory (SRAM), electrically erasable programmable read-only memory (EEPROM), erasable programmable read-only memory (EPROM), programmable read-only memory (PROM), read-only memory (ROM), magnetic memory, flash memory, magnetic disk, or optical disk.

The power component 806 provides power to various components of the UE 800. The power component 806 may include a power management system, one or more power supplies, and other components associated with generating, managing, and distributing power to the UE 800.

The multimedia component 808 includes a screen that provides an output interface between the UE 800 and the user. In some embodiments of the present disclosure, the screen may include a liquid crystal display (LCD) and a touch panel (TP). If the screen includes a touch panel, the screen may be implemented as a touch screen to receive input signals from the user. The touch panel includes one or more touch sensors to sense touch, slide, and gestures on the touch panel. The touch sensor may not only sense the boundaries of the touch or slide action, but also detect the duration and pressure associated with the touch or slide operation. In some embodiments of the present disclosure, the multimedia component 808 includes a front camera and/or a rear camera. When the UE 800 is in an operating mode, such as a shooting mode or a video mode, the front camera and/or the rear camera may receive external multimedia data. Each front camera and rear camera may be a fixed optical lens system or have focal length and optical zoom capabilities.

The audio component 810 is configured to output and/or input audio signals. For example, the audio component 810 includes a microphone (MIC), and when the UE 800 is in an operating mode, such as a call mode, a recording mode, and a speech recognition mode, the microphone is configured to receive an external audio signal. The received audio signal may be further stored in the memory 804 or sent via the communication component 816. In some embodiments of the present disclosure, the audio component 810 also includes a speaker for outputting an audio signal.

I/O interface 812 provides an interface between the processing component 802 and peripheral interface modules, such as keyboards, click wheels, buttons, etc. These buttons may include but are not limited to: home button, volume button, start button, and lock button.

The sensor assembly 814 includes one or more sensors for providing various aspects of status assessment for the UE 800. For example, the sensor assembly 814 can detect the open/closed state of the device 800, the relative positioning of components, such as the display and keypad of the UE 800, the sensor assembly 814 can also detect the position change of the UE 800 or a component of the UE 800, the presence or absence of user contact with the UE 800, orientation or acceleration/deceleration of the UE 800 and the temperature change of the UE 800. The sensor assembly 814 can include a proximity sensor configured to detect the presence of nearby objects without any physical contact. The sensor assembly 814 can also include a light sensor, such as a CMOS or CCD image sensor, for use in imaging applications. In some embodiments of the present disclosure, the sensor assembly 814 can also include an acceleration sensor, a gyroscope sensor, a magnetic sensor, a pressure sensor or a temperature sensor.

The communication component 816 is configured to facilitate wired or wireless communication between the UE 800 and other devices. The UE 800 can access a wireless network based on a communication standard, such as WiFi, 2G or 3G, or a combination thereof. In an exemplary embodiment, the communication component 816 receives a broadcast signal or broadcast-related information from an external broadcast management system via a broadcast channel. In an exemplary embodiment, the communication component 816 also includes a near field communication (NFC) module to facilitate short-range communication. For example, the NFC module can be implemented based on radio frequency identification (RFID) technology, infrared data association (IrDA) technology, ultra-wideband (UWB) technology, Bluetooth (BT) technology and other technologies.

In an exemplary embodiment, UE 800 may be implemented by one or more application-specific integrated circuits (ASICs), digital signal processors (DSPs), digital signal processing devices (DSPDs), programmable logic devices (PLDs), field programmable gate arrays (FPGAs), controllers, microcontrollers, microprocessors, or other electronic components to perform the above methods.

In an exemplary embodiment, a non-transitory computer-readable storage medium including instructions is also provided, such as a memory 804 including instructions, and the above instructions can be executed by the processor 820 of the UE 800 to generate the above method. For example, the non-transitory computer-readable storage medium can be a ROM, a random access memory (RAM), a CD-ROM, a magnetic tape, a floppy disk, an optical data storage device, etc.

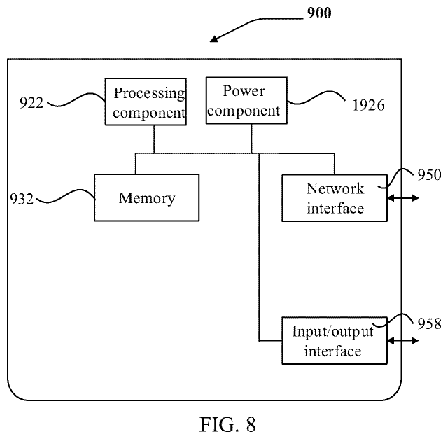

As shown in FIG. 8, an embodiment of the present disclosure shows a structure of a communication device. For example, the communication device 900 may be provided as a network device. The network device may be the aforementioned gNB, LMF, OAM and/or NWDAF.

Referring to FIG. 8, the communication device 900 includes a processing component 922, which further includes one or more processors, and a memory resource represented by a memory 932 for storing instructions executable by the processing component 922, such as an application. The application stored in the memory 932 may include one or more modules, each corresponding to a set of instructions. In addition, the processing component 922 is configured to execute instructions to perform any of the aforementioned methods applied to the access device, for example, at least one of the methods shown in FIGS. 2A to 2C, FIGS. 3A to 3B, and FIGS. 4A to 4C.

The communication device 900 may also include a power component 1926 configured to perform power management of the communication device 900, a wired or wireless network interface 950 configured to connect the communication device 900 to a network, and an input/output (I/O) interface 958. The communication device 900 may operate based on an operating system stored in the memory 932, such as Windows Server™, Mac OS X™, Unix™, Linux™, FreeBSD™, or the like.

Those skilled in the art will readily appreciate other implementations of the embodiments of the present disclosure after considering the specification and practicing the contents disclosed herein. The present disclosure is intended to cover any variations, uses, or adaptations of the embodiments of the present disclosure, which follow the general principles of the embodiments of the present disclosure and include common knowledge or customary technical means in the art that are not disclosed in the present disclosure. The specification and examples are to be considered merely as exemplary, and the true scope and spirit of the embodiments of the present disclosure are indicated by the following claims.

It should be understood that the embodiments of the present disclosure are not limited to the precise structures described above and shown in the drawings, and various modifications and changes may be made without departing from the scope thereof. The scope of the embodiments of the present disclosure is limited only by the appended claims.

1. An information processing method, wherein the method is performed by a first communication device, the method comprising:
receiving a data set from a second communication device; and
training an artificial intelligence (AI)/machine learning (ML) model using the data set, wherein the AI/ML model is at least used for positioning.

2. The method according to claim 1, wherein the data set comprises at least one of following data:
a measurement result and location information;
the measurement result and indication information;
the measurement result, the location information, and the indication information; or
the measurement result;, and
wherein the measurement result comprises a measurement result of a positioning reference signal; the location information comprises location information of a measuring device and/or location information of a measured device; and the indication information is used to indicate that a measurement path for obtaining the measurement result is a line-of-sight (LoS) or a non-line-of-sight (NLoS).

3. The method according to claim 2, wherein the measurement result comprises: a first measurement result and a second measurement result, and the first measurement result is different from the second measurement result.

4. The method according to claim 3, wherein the second measurement result comprises at least one of:
a reference signal received power (RSRP) obtained by measuring the positioning reference signal;
a reference signal received path power (PRSPP) obtained by measuring the positioning reference signal; or
a channel impulse response (CIR) obtained by measuring the positioning reference signal.

5. The method according to claim 1, wherein the method further comprises:
sending a request message to the second communication device, wherein the request message is used to request the data set from the second communication device.

6. The method according to claim 5, wherein the request message comprises description information of the data set, and the description information of the data set indicates at least one of: a type of a data set, a data format, an amount of data, a collection scene, a collection location, and a reference signal configuration corresponding to the data set.

7. The method according to claim 6, wherein receiving the data set from the second communication device comprises: receiving the data set provided by the second communication device according to the description information.

8. The method according to claim 1, wherein
the first communication device is a location management function (LMF), and the second communication device is: a user equipment (UE) and/or an access network device; or,
the first communication device is the UE, and the second communication device is the LMF and/or the access network device; or,
the first communication device is the access network device, and the second communication device is: the UE and/or the LMF; or;
the first communication device is an operation administration and maintenance (OAM), and the second communication device is: the access network device and/or the LMF; or
the first communication device is a network data analysis function (NWDAF), and the second communication device is any one of: the access network device, the OAM, the LMF, the UE.

9. The method according to claim 1, wherein the second communication device is a UE, and the method further comprises: receiving data capability information sent by the UE; wherein the data capability information indicates whether the UE has a capability to provide the data set.

10. The method according to claim 9, wherein the method further comprises: sending a data capability request message to the UE, wherein the data capability request message is used to request and instruct the UE to provide the data capability information.

11. The method according to claim 9, wherein the data capability information of the UE is used to indicate at least one of: a type of a data set supported by the UE, a data format supported by the UE, an amount of data supported by the UE, a collection scene supported by the UE, a collection location supported by the UE, and a reference signal configuration corresponding to the data set supported by the UE.

12. The method according to claim 1, wherein the type of the data set is one of:
a first type, a data set with a data element being a measurement result and location information; wherein the measurement result is a measurement result of a positioning reference signal; wherein the location information comprises: location information of a measuring device and/or location information of a measured device;
a second type, a data set with the data element being the measurement result and indication information; wherein the measurement result is the measurement result of the positioning reference signal; the indication information indicates that a measurement path for obtaining the measurement result is a line-of-sight (LoS) or a non-line-of-sight (NLoS); and
a third type, a data set with the data element being the measurement result.

13. The method according to claim 3, wherein the collection scene is one of: an outdoor scene, an indoor scene, a predetermined building scene, or a predetermined use scene.

14. The method according to claim 3, wherein the collection location comprises at least one of:
a cell identifier, indicating a cell corresponding to a place where the data set is generated;
a base station identifier, indicating a base station corresponding to the place where the data set is generated;
a transmission reception point identifier, indicating a transmission reception point corresponding to the place where the data set is generated; or
UE location information, indicating a UE location when the UE collects data.

15. The method according to claim 3, wherein the reference signal configuration comprises: a downlink positioning reference signal (PRS) configuration; a surrounding reference signal (SRS) configuration.

16. An information processing method, wherein the method is performed by a second communication device, the method comprising:
sending a data set to a first communication device, and
wherein the data set is used to train an artificial intelligence (AL)/machine learning (ML) model, wherein the AI/ML model is at least used for positioning.

17-19. (canceled)

20. The method according to claim 16, wherein the method further comprises: receiving a request message sent by the first communication device, wherein the request message is used to request the data set from the second communication device.

21. The method according to claim 20, wherein the request message comprises description information of the data set, and the description information of the data set indicates at least one of: a type of a data set, a data format, an amount of data, a collection scene, a collection location, and a reference signal configuration corresponding to the data set,
wherein sending the data set to the first communication device comprises: sending the data set to the first communication device according to the description information.

22-30. (canceled)

31. An information processing apparatus, comprising: a processor, a transceiver, a memory and an executable program stored in the memory and capable of being run by the processor, wherein the processor is configured to:
receive a data set from a second communication device; and
train an artificial intelligence (AI)/machine learning (ML) model using the data set, wherein the AI/ML model is at least used for positioning.

32. An information processing apparatus, comprising: a processor, a transceiver, a memory and an executable program stored in the memory and capable of being run by the processor, wherein the processor performs the method according to claim 16.

33-36. (canceled)
